(19) United States
(12) Patent Application Publication
(10) Pub. No.: US 2025/0220973 A1
(43) Pub. Date: Jul. 3, 2025

(54) HIGH ELECTRON MOBILITY TRANSISTOR AND METHOD OF MANUFACTURING THE SAME

(71) Applicant: Powerchip Semiconductor Manufacturing Corporation, Hsinchu (TW)

(72) Inventors: Jih-Wen Chou, Hsinchu (TW); Yu-Jen Huang, Hsinchu (TW); Chia-Hao Chang, Hsinchu (TW); Tian-Li Wu, Hsinchu (TW)

(73) Assignee: Powerchip Semiconductor Manufacturing Corporation, Hsinchu (TW)

(21) Appl. No.: 18/591,000

(22) Filed: Feb. 29, 2024

(30) Foreign Application Priority Data
Jan. 2, 2024 (TW) 113100060

(51) Int. Cl. H01L 29/47; H01L 21/02; H01L 29/20; H01L 29/40; H01L 29/66; H01L 29/778

(52) U.S. Cl. CPC H10D 30/675; H01L 21/02178; H10D 30/015; H10D 30/475; H10D 30/6738; H10D 62/85; H10D 62/8503; H10D 64/01; H10D 64/64

(57) ABSTRACT

A high electron mobility transistor (HEMT) is provided in the present invention, including an AlGaN layer on a GaN substrate, a gate comprised of a first p-GaN layer on the AlGaN layer, an etch stop layer on the first p-GaN layer, a second p-GaN layer on the etch stop layer and an electrode layer on the second p-GaN layer, and a source and a drain respectively on the AlGaN layer at two sides of the gate in a first direction, wherein a width of the first p-GaN layer in the first direction is larger than a width of the second p-GaN layer in the first direction, so that the first p-GaN layer is provided with a ledge part protruding in the first direction.

### BACKGROUND OF THE INVENTION

### 1. Field of the Invention

The present invention relates generally to a high electron mobility transistor, and more specifically, to a high electron mobility transistor with dual p-GaN layers and a ledge structure.

### 2. Description of the Prior Art

Most of semiconductor devices currently available in the world are silicon-based semiconductor using silicon as their substrate and channel. However, in the application of high-temperature, high-voltage, and high-power devices, silicon-based devices may suffer high power consumption since their on-state resistance R_{DS} (on) is too large. Furthermore, in high-frequency operation, silicon-based device has relatively lower switch frequency, thus its performance is no match for those using wide-bandgap compound semiconductor material like gallium nitride (GaN) or silicon carbide (SiC). In comparison to conventional silicon-based material, wide-bandgap compound semiconductor material like GaN is provided with larger bandgap, lower on-state resistance, thus it is more durable and applicable in high temperature, high voltage, high frequency and high current applications, and also with better energy conversion efficiency. Thus, GaN device is provided with all kinds of excellent properties required in the semiconductor device like good heat dissipation, small size, lower power consumption and high power, which is suitable for the application of power semiconductor. With the urgent demand in high-end industry like 5G communication and electric car, GaN material has emerged to be a promising candidate of the third generation semiconductor materials in the future.

There are primarily two modes of GaN device, i.e. depletion mode (D-mode) and enhancement mode (E-mode). With respect to D-mode GaN device, since a conductive channel of high concentration two-dimensional electron gas (2DEG) will be formed at the heterojunction between AlGaN/GaN layers due to spontaneous polarization and piezoelectric polarization effect, the D-mode GaN device is normally-on without applying gate voltage, while E-mode device realizes its normally-off characteristic through setting an additional positively charged p-type GaN (p-GaN) layer on the aforementioned AlGaN layer to achieve the purpose of depleting the 2DEG channel below. The aforementioned two modes of GaN devices have their advantages, disadvantages and their suitable applications.

In conventional skill, high electric filed is usually formed on the edge of gate in E-mode GaN power device due to the operating environment of high drain voltage, so that reliability issue may occur in high temperature reverse bias (HTRB) test and hard switching operation. Accordingly, those skilled in the art need to improve current process and structure of GaN device in order to solve this problem.

### SUMMARY OF THE INVENTION

In the light of the aforementioned disadvantage in prior art, the present invention hereby provides a novel high electron mobility transistor (HEMT) structure, featuring dual p-GaN layers in HEMT device, with one of the p-GaN layers having horizontally protruding ledge part, so as to form MOS-like lightly doped drain (LDD) structure to enhance the effect of reduced-surface-field (RESURF) in the operation of high drain voltage, improving withstand voltage of HEMT power device, solving reliability issue in high temperature reverse bias (HTRB) test and hard switching operation in conventional skill, which is the efficacy and advantage of the structure of present invention.

One aspect of the present invention is to provide a high electron mobility transistor, with structure including a GaN substrate, a AlGaN layer on the GaN substrate, a gate including a first p-GaN layer on the AlGaN layer, an etch stop layer on the first p-GaN layer, a second p-GaN layer on the etch stop layer and an electrode layer on the second p-GaN layer, and a source and a drain respectively on the AlGaN layer at two sides of the gate in a first direction, wherein the width of first p-GaN layer in the first direction is larger than the width of second p-GaN layer in the first direction, so that the first p-GaN layer is provided with a ledge part protruding in the first direction.

Another aspect of the present invention is to provide a method of manufacturing high electron mobility transistor, including steps of providing a GaN substrate, forming an AlGaN layer, a first p-GaN layer, an etch stop layer, a second p-GaN layer and an electrode layer sequentially on the GaN substrate, performing a first photolithography process to pattern the electrode layer and the second p-GaN layer until the etch stop layer is exposed, performing a second photolithography process to pattern the etch stop layer and the first p-GaN layer until the AlGaN layer is exposed, so that the first p-GaN layer is provided with a ledge part protruding in a first direction, and forming a source and a drain respectively on the AlGaN layer at two sides of the first p-GaN layer and the second p-GaN layer in the first direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a high electron mobility transistor (HEMT) in accordance with one embodiment of the present invention;

FIG. 2 is a flow chart of manufacturing a HEMT in accordance with one embodiment of the present invention; and

FIGS. 3-8 are schematic cross-sectional views illustrating a process flow of manufacturing the HEMT in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

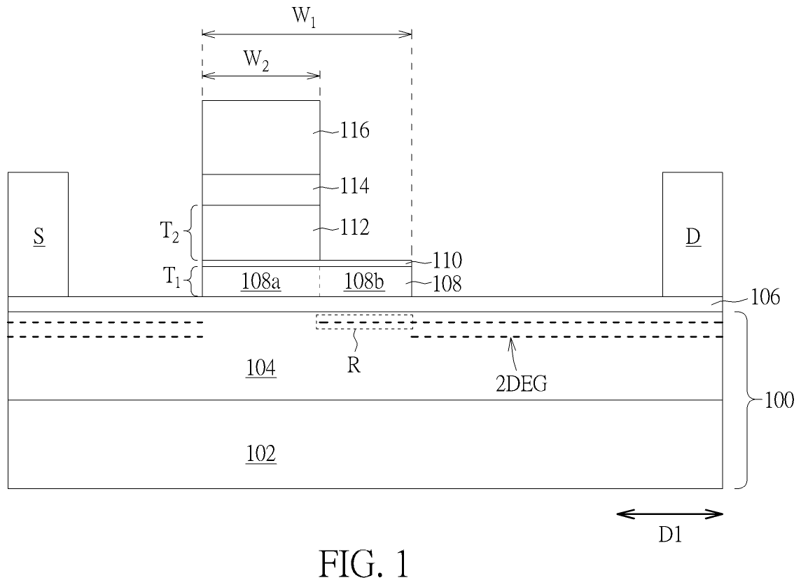

First, please refer to FIG. 1, which is a schematic cross-sectional view of a high electron mobility transistor (HEMT) provided by the present invention. As shown in FIG. 1, the HEMT of present invention includes a gallium nitride (GaN) substrate 100 as a base for setting device. In the embodiment of present invention, the GaN substrate 100 may be formed on a silicon wafer or sapphire substrate (not shown) through heteroepitaxy, with structure like buffer layer or superlattice layer therebetween to reduce lattice dislocation or defect. For the clarity of drawings, only the layer structures above GaN substrate 100 are shown in the figure, which may include a carbon-doped GaN layer 102 and a GaN layer 104, wherein the presence of carbon-doped GaN layer 102 may significantly improve the punch-through voltage and withstand voltage of the HEMT device and reduce its vertical leakage current, while the GaN layer 104 functions as a channel layer for the HEMT device. An aluminum gallium nitride (AlGaN) layer 106 is formed on the surface of GaN layer 100 with a thickness about 14-16 nm, covering entire surface of the GaN substrate 100 and directly contacting the GaN layer 104. In this way, a heterojunction will be formed between the AlGaN layer 106 and the GaN layer 104, with property of energy-gap discontinuity therebetween to make the electrons resulted from polarization effect in the AlGaN layer 106 falling into the GaN layer 104, thereby forming a high mobility and conductive electron film, ex. a two-dimension electron gas (2DEG) channel adjacent to the interface of the two layers.

Refer still to FIG. 1. In order to manufacture an enhancement mode (E-mode) GaN device with normally-off property, a positive charged gate structure is required on the AlGaN layer 106 to deplete or suppress the 2DEG channel below. In the embodiment of present invention, the gate is provided with components like a first p-GaN layer 108, an etch stop layer 110, a second p-GaN layer 112 and an electrode layer 114 sequentially on the GaN substrate 100. The feature of present invention is that, as shown in FIG. 1, the p-GaN layer for depleting the 2DEG channel is a dual-layer structure made of the first p-GaN layer 108 and the second p-GaN layer 112, with the etch stop layer 110 isolated therebetween. The first p-GaN layer 108 is set on the surface of AlGaN layer 106, with its thickness T₁ about 20-40 nm (in a direction vertical to the substrate, and the thickness referred hereinafter are all based on this direction). The presence of first p-GaN layer 108 may reduce the concentration of 2DEG channel therebelow to lower its conductivity. The etch stop layer 110 is formed on entire surface of the first p-GaN layer 108, with its material might be AlGaN or aluminum nitride (AlN) and its thickness might be about 1-4 nm. The etch stop layer 110 is used as a stop layer in the process of forming the dual p-GaN layers. The second p-GaN layer 112 is formed on the surface of etch stop layer 110, with its thickness T₂ (about 50-60 nm) preferably larger than the thickness T₁ of first p-GaN layer 108 in order to completely deplete the 2DEG channel and form a gate switching region. In the embodiment of present invention, please note that the width W₁ of first p-GaN layer 108 in horizontal first direction D1 (i.e. the current direction between the source and drain of HEMT device) is larger than the width of second p-GaN layer 112 in the first direction D1, so that the first p-GaN layer 108 is provided with a ledge part 108b protruding in the first direction D1, which is an important feature of the present invention.

More specifically, in the preferred embodiment of present invention as shown in FIG. 1, sidewalls of the first p-GaN layer 108 and second p-GaN layer 112 are flush at a side opposite to the ledge part 108b. The part of first p-GaN layer 108 overlapping the second p-GaN layer 112 in the direction vertical to the substrate is its main part 108a, and the part not overlapping the second p-GaN layer 112 is its ledge part 108b. The ledge part 108b is preferably protruding toward the drain D of HEMT device to achieve the effect of reduced-surface-field (RESURF), but not limited thereto. In other embodiment, the first p-GaN layer 108 may be provided with a ledge part protruding toward the source S, depending on the requirement of device. In the embodiment of present invention as shown in FIG. 1, since the presence of second p-GaN layer 112, the 2DEG channel once having its concentration reduced by the first p-GaN layer 108 will be completely depleted, thereby forming a semiconductor switching region under the main part 108a. Only when a voltage is applied from the gate on this region will form a conductive channel, that is the normally-off property required by E-mode HEMT device. Furthermore, in the embodiment of present invention, the region of 2DEG channel without any p-GaN structure thereon has maximum concentration (about 8×10¹² cm⁻³) to function as a channel for the device. On the other hand, the partly-depleted region R of 2DEG channel has lower concentration (about 5×10¹¹ cm⁻³), which may function as a lightly-doped drain (LDD) structure like in a MOS device to achieve RESURF effect, thereby solving reliability issue in high temperature reverse bias (HTRB) test and hard switching operation in conventional skill, which is the efficacy and advantage of the structure of present invention.

Refer still to FIG. 1. An electrode layer 114 and a hard mask layer 116 are further provided on the dual p-GaN layers of present invention. The electrode layer 114 is formed on the surface of second p-GaN layer 112, with its material might be titanium nitride (TiN) to provide good Schottky contact for the p-GaN layer of gate structure and contacts formed later. The hard mask layer 116 is formed on the surface of electrode layer 114, with its material might be silicon nitride (Si₃N₄) to function as a hard mask in the process of patterning the second p-GaN layer 112. In the embodiment of present invention, the hard mask layer 116, electrode layer 114 and second p-GaN layer 112 overlap each other substantially in the direction vertical to the substrate, while the first p-GaN layer 108 protrudes in the horizontal first direction D1. In addition, a source S and a drain D are formed respectively on the AlGaN layer 106 at two sides of the gate structure in the first direction D1, with its material might be titanium (Ti) or aluminum (Al) to provide good contact for the AlGaN layer 106 and contacts formed later. In order to increase the breakdown voltage of power device, the distance between drain D and first p-GaN layer 108 is preferably larger than the distance between source S and first p-GaN layer 108. The aforementioned gate structure, including the first p-GaN layer 108, etch stop layer 110, second p-GaN layer 112 and electrode layer 114, constitutes the HEMT of present invention collectively with the source S and drain D.

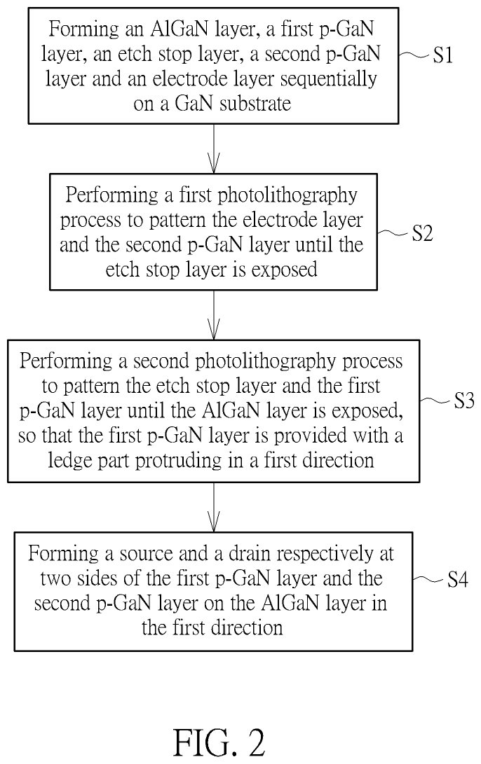

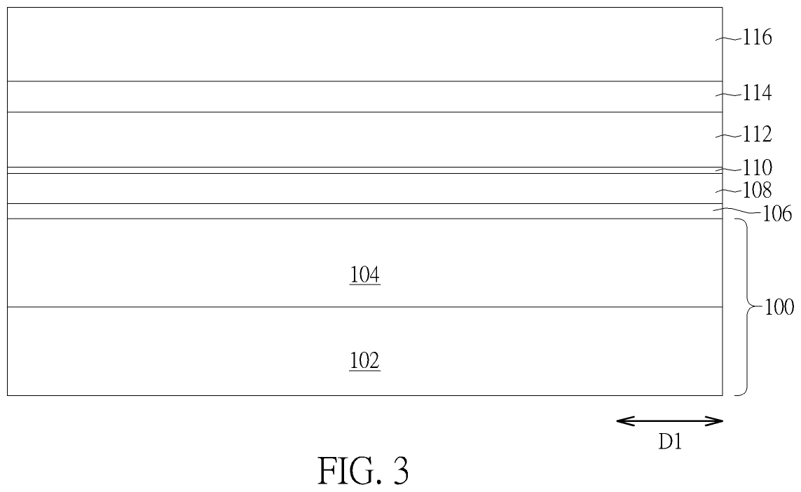

Please refer now to FIG. 2, which is a flow chart of manufacturing the aforementioned HEMT in accordance with one embodiment of the present invention, and please refer simultaneously and sequentially to the cross-sectional views of FIGS. 3-7 for better understanding relative positions and connections of components in the HEMT device in vertical direction.

First, please refer to FIG. 3. In step S1, a GaN substrate 100 is provided as a base for setting the device. The GaN substrate 100 may include a carbon-doped GaN layer 102 and a GaN layer 104 formed on the carbon-doped GaN layer 102. The carbon-doped GaN layer 102 and GaN layer 104 may be formed on a silicon wafer or sapphire substrate (not shown) through heteroepitaxy. Thereafter, an AlGaN layer 106, a first p-GaN layer 108, an etch stop layer 110, a second p-GaN layer 112, an electrode layer 114 and a hard mask layer 116 are formed sequentially on the GaN substrate 100 to serve as material layers for forming components of the HEMT in present invention. In real implementation, the AlGaN layer 106, first p-GaN layer 108, etch stop layer 110, second p-GaN layer 112 may all be formed in the same process chamber of forming the GaN substrate 100 through in-situ, continuous heteroepitaxy, without needing to transfer the wafer to other process chamber, therefore saving manufacturing cost and reducing contamination risk. In the embodiment of present invention, the thickness of AlGaN layer 106 is about 14-16 nm, wherein the percentage composition of Al is about 22.5%. The thickness of first p-GaN layer 108 is about 20-40 nm, wherein the p-type dopants doped therein may include but not limit to carbon (C), iron (Fe), magnesium (Mg) or zinc (Zn). The material of etch stop layer 110 may be AlGaN or AlN, with thickness about 1-4 nm, wherein the percentage composition of Al is about 22.5%-30%. The second p-GaN layer 112 is also doped with p-type dopant, with its thickness preferably larger than the thickness of first p-GaN layer 108, about 50-60 nm. The material of electrode layer 114 may be TiN, which may be formed through sputtering or physical vapor deposition (PVD). The material of hard mask layer 116 may be Si₃N₄, which may be formed through chemical vapor deposition (CVD).

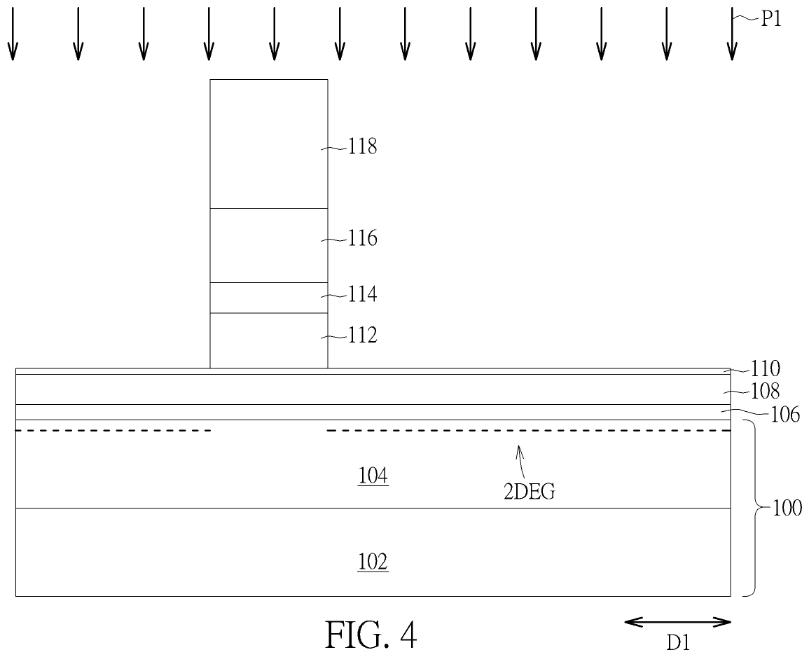

Please refer next to FIG. 4. After the aforementioned material layers are formed, in step S2, a first photolithography process P1 is performed to pattern the hard mask layer 116, electrode layer 114 and second p-GaN layer 112 until the etch stop layer 110 is exposed. More specifically, in the first photolithography process P1, a first photoresist 118 is first formed on the hard mask layer 116. Pattern of gate structure is defined in the first photoresist 118 through exposure and development steps, i.e. the pattern of main part 108a of first p-GaN layer 108 shown in FIG. 1. Next, a dry etching process is performed using the patterned first photoresist 118 to remove exposed hard mask layer 116, electrode layer 114 and second p-GaN layer 112 below. The etching process may first transfer the gate pattern to the hard mask layer 116, then the patterned hard mask layer 116 is used as a mask to proceed the etching of electrode layer 114 and second p-GaN layer 112. Furthermore, this etching step uses the etch stop layer 110 between first p-GaN layer 108 and second p-GaN layer 112 as a stop layer to better control the thickness of ledge part 108b of first p-GaN layer. It can be seen in the figure that, since the p-GaN structure for suppressing the polarization effect of AlGaN becomes thinner, 2DEG channel will be formed in the region of GaN layer 104 that has no second p-GaN layer 112 thereon, with its concentration about 5×10¹¹ cm⁻³. The first photoresist 118 may then be removed after the first photolithography process P1.

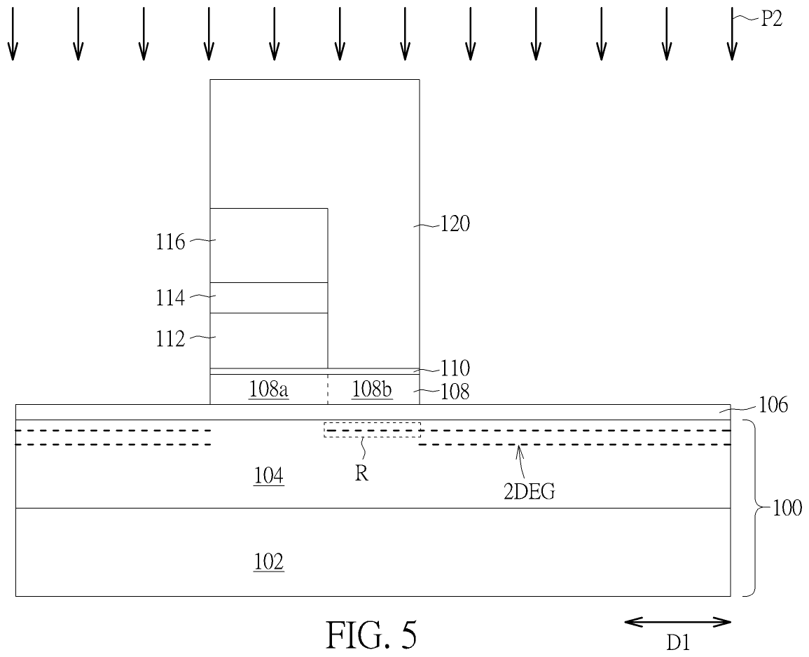

Please refer next to FIG. 5. After the first photolithography process P1, in step P3, a second photolithography process P2 is performed to pattern the etch stop layer 110 and first p-GaN layer 108 until the AlGaN layer 106 below is exposed. More specifically, in the second photolithography process P2, a second photoresist 120 is first formed on the surface of substrate 100. Pattern of required first p-GaN layer 108 is defined in the second photoresist 120 through exposure and development steps, which covers the hard mask layer 116 and etch stop layer 110. The second photoresist generally covers entire hard mask layer 116 and parts of the first p-GaN layer 108, including the patterns of aforementioned main part 108a and ledge part 108b. Next, a dry etching process is performed using the patterned second photoresist 120 as a mask to remove exposed etch stop layer 110 and first p-GaN layer 108 below, thereby forming the pattern of first p-GaN layer 108 with the main part 108a and the ledge part 108b protruding in the first direction D1. It can be seen in the figure that, since the p-GaN structure for suppressing the polarization effect of AlGaN is completely removed, 2DEG channel with higher concentration will be formed in the region of GaN layer 104 that has no first p-GaN layer 108 and second p-GaN layer 112 thereon, with a concentration about 8×10¹² cm⁻³. In this photolithography step, a certain thickness (ex. 2 nm) of the AlGaN layer 106 might be removed, resulting minor decrease of 2DEG concentration. The second photoresist 120 may then be removed after the second photolithography process P2.

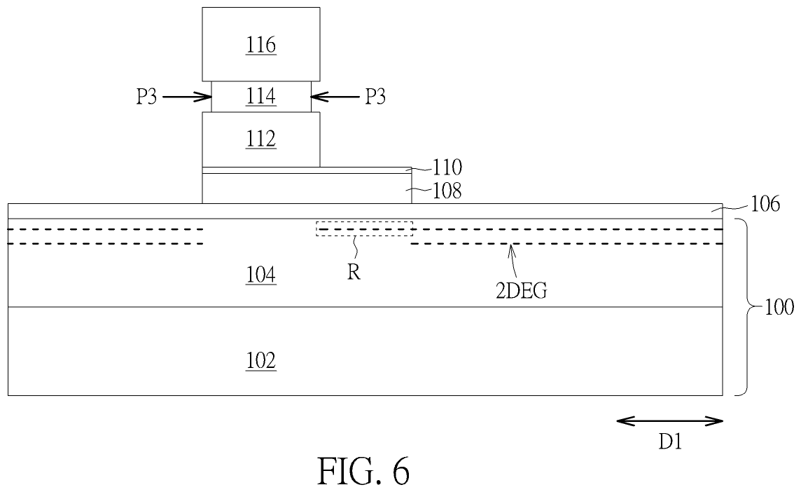

Please refer next to FIG. 6. After the second photolithography process P2, optionally, a trimming process P3 may be performed using the hard mask layer 116 as a mask to reduce the width of electrode layer 114 in the first direction D1 and make its width smaller than the width of second p-GaN layer 112 below in the first direction D1, which is beneficial to control the width and electrical field of gate switching region thereunder and reduce leakage current. The trimming process P3 may be a selective lateral etching step directed to TiN material, ex. a wet etching process using SPM (H₂SO₄/H₂O₂) etchant plus APM (NH₄OH/H₂O₂) etchant.

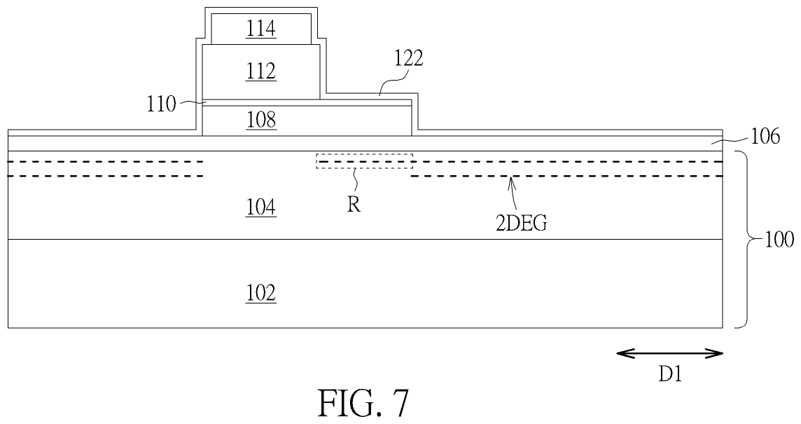

Please refer next to FIG. 7. After the trimming process P3, the hard mask layer 116 may then be removed to expose the surface of electrode layer 114. Thereafter, a conformal passivation layer 122 is formed on entire surface of the substrate 100 to protect the gate structure. In the embodiment of present invention, the material of passivation layer 122 may be Al₂O₃ or AlN, which may be formed with a thickness about 1-4 nm through atomic layer deposition (ALD). In other embodiment, the passivation layer 122 may be formed after source S and drain D.

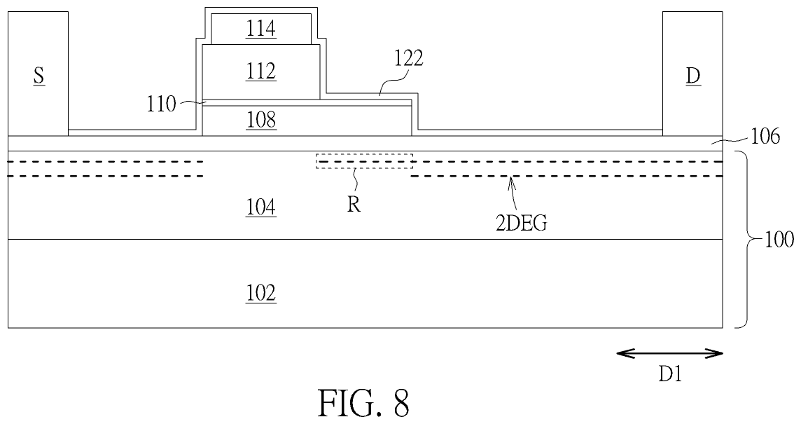

Please refer next to FIG. 8. After the passivation layer 122 is formed, in step S4, a source S and a drain D are formed respectively at two sides of the first p-GaN layer 108 and second p-GaN layer 112 on the AlGaN layer 106 in the first direction D1. More specifically, this step may include forming a photoresist first on the substrate 100 with openings defining the patterns of source S and drain D. The passivation layer 122 exposed from the photoresist is then removed to expose the AlGaN layer 106 below. Thereafter, conductive metal, ex. Ti or Al, is formed on the exposed AlGaN layer 106, thereby forming the source S and drain D contacting the AlGaN layer 106. In other embodiment, the aforementioned passivation layer 122 may be formed after the source S and drain D.

According to the aforementioned embodiment, it can be understood that the feature of present invention lies in the dual p-GaN layers in HEMT device, with one of the p-GaN layers having horizontally protruding ledge part to form LDD structure like in the one in MOS device to enhance RESURF effect in the operation of high drain voltage as well as reduce the cut-off current between gate and drain, thereby improving the withstand voltage of HEMT power device, solving reliability issue in high HTRB test and hard switching operation in conventional skill, which is the efficacy and advantage of the structure of present invention. In addition, an etch stop layer is set in the dual p-GaN layers to better control the thickness of ledge part of the p-GaN layer, thereby forming a 2DEG channel with required concentration in the GaN layer under the ledge part.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high electron mobility transistor, comprising:
a GaN substrate;
an AlGaN layer on said GaN substrate;
a gate, comprising:
a first p-GaN layer on said AlGaN layer;
an etch stop layer on said first p-GaN layer;
a second p-GaN layer on said etch stop layer; and
an electrode layer on said second p-GaN layer; and
a source and a drain respectively on said AlGaN layer at two sides of said gate in a first direction;
wherein a width of said first p-GaN layer in said first direction is larger than a width of said second p-GaN layer in said first direction, so that said first p-GaN layer is provided with a ledge part protruding in said first direction.

2. The high electron mobility transistor of claim 1, wherein said ledge part protrudes toward said drain.

3. The high electron mobility transistor of claim 1, wherein sidewalls of said first p-GaN layer and said second p-GaN layer are flush at a side opposite to said ledge part.

4. The high electron mobility transistor of claim 1, wherein a width of said electrode layer in said first direction is smaller than said width of said second p-GaN layer in said first direction.

5. The high electron mobility transistor of claim 1, wherein a material of said etch stop layer is AlGaN or AlN.

6. The high electron mobility transistor of claim 1, wherein a material of said electrode layer is TiN.

7. The high electron mobility transistor of claim 1, wherein a thickness of said second p-GaN in a direction vertical to said GaN substrate is larger than a thickness of said first p-GaN in said direction vertical to said GaN substrate.

8. The high electron mobility transistor of claim 1, wherein said GaN substrate comprises a carbon-doped GaN layer and a GaN layer, and said GaN layer is between said carbon-doped GaN layer and said AlGaN layer.

9. A method of manufacturing high electron mobility transistor, comprising:
providing a GaN substrate;
forming an AlGaN layer, a first p-GaN layer, an etch stop layer, a second p-GaN layer and an electrode layer sequentially on said GaN substrate;
performing a first photolithography process to pattern said electrode layer and said second p-GaN layer until said etch stop layer is exposed;
performing a second photolithography process to pattern said etch stop layer and said first p-GaN layer until said AlGaN layer is exposed, so that said first p-GaN layer is provided with a ledge part protruding in a first direction; and
forming a source and a drain respectively on said AlGaN layer at two sides of said first p-GaN layer and said second p-GaN layer in said first direction.

10. The method of manufacturing high electron mobility transistor of claim 9, further comprising forming a conformal passivation layer covering said AlGaN layer, said first p-GaN layer, said etch stop layer, said second p-GaN layer and said electrode layer after said second photolithography process.

11. The method of manufacturing high electron mobility transistor of claim 10, wherein a material of said passivation layer is Al₂O₃ or AlN.

12. The method of manufacturing high electron mobility transistor of claim 9, further comprising forming a hard mask layer on said electrode layer, and said first photolithography process also patterns said hard mask layer.

13. The method of manufacturing high electron mobility transistor of claim 12, further comprising removing patterned said hard mask layer after said second photolithography process.

14. The method of manufacturing high electron mobility transistor of claim 12, further comprising performing a trimming process using patterned said hard mask layer to reduce a width of said electrode layer in said first direction after said second photolithography process.

15. The method of manufacturing high electron mobility transistor of claim 9, wherein said second photolithography process makes said ledge part protruding toward said drain.

16. The method of manufacturing high electron mobility transistor of claim 9, wherein said second photolithography process makes sidewalls of said first p-GaN layer and said second p-GaN layer flush at a side opposite to said ledge part.
